(19) United States
(12) Patent Application Publication
(10) Pub. No.: US 2025/0015242 A1
(43) Pub. Date: Jan. 9, 2025

(54) DISPLAY DEVICE

(71) Applicant: LG ELECTRONICS INC., Seoul (KR)

(72) Inventors: Younghak CHANG, Seoul (KR); Sukkoo JUNG, Seoul (KR); Hyungseok BANG, Seoul (KR)

(73) Assignee: LG ELECTRONICS INC., Seoul (KR)

(21) Appl. No.: 18/711,005

(22) PCT Filed: Nov. 16, 2021
(86) PCT No.: PCT/KR2021/016732

§ 371 Date: May 16, 2024

(51) Int. Cl. H01L 33/62; H01L 25/16

(52) U.S. Cl. CPC H01L 33/62; H01L 25/167

(57) ABSTRACT

A display device includes a substrate including a plurality of pixels, and semiconductor light emitting device in each of the plurality of pixels. The substrate may include an electrode pad part, and the semiconductor light emitting device includes electrodes. The electrode is disposed on the electrode pad part, and at least one of the electrode pad part or the electrode may have a texture structure.

### TECHNICAL FIELD

The embodiment relates to a display device.

### BACKGROUND ART

Display devices are being used in various fields. In particular, recently, not only the TV display field but also the virtual reality (VR: Virtual Reality) or augmented reality (AR)-based display field and the vehicle head-up display (HUD: Head-Up Display) field have been receiving great attention.

These AR and HUD display devices require not only high resolution but also high definition. Accordingly, display devices that display images using high-brightness, small-sized light emitting diodes as light sources for pixels are attracting attention.

Light emitting diodes exhibit excellent durability even under harsh environmental conditions, and are capable of long lifespan and high brightness, so they are attracting attention as a light source for next-generation display devices.

Recently, ultra-small light emitting diodes have been manufactured using highly reliable inorganic crystal structure materials and placed on the panel of a display device (hereinafter referred to as “display panel”), so research is underway to use it as a next-generation light source.

These display devices are expanding beyond flat panel displays into various forms such as flexible displays, foldable displays, stretchable displays, and rollable displays.

In order to realize high resolution, the size of the pixels is gradually becoming smaller, and the light emitting devices are to be aligned in numerous pixels of this smaller size, research into the manufacture of ultra-small light emitting diodes as small as micro or nano scale is being actively conducted.

Typically, display devices contain tens of millions of pixels or more. Accordingly, because it is very difficult to align at least one light emitting device in each of tens of millions of small pixels, various studies on ways to align light emitting devices in a display panel are being actively conducted.

As the size of light emitting devices becomes smaller, quickly and accurately transferring these light emitting devices onto the substrate is becoming a very important problem to solve. Transfer technologies that have been recently developed include the pick and place process, laser lift-off method, or self-assembly method. In particular, the self-assembly method of transferring a light emitting device onto a substrate using a magnetic material (or magnet) has recently been in the spotlight.

In the self-assembly method, numerous light emitting devices are dropped into a mold containing a fluid, and as the magnetic material moves, the light emitting devices dropped into the fluid are moved to the pixels of the substrate, and the light emitting devices are aligned at each pixel. Therefore, the self-assembly method is attracting attention as a next-generation transfer method because it may quickly and accurately transfer numerous light emitting devices onto the substrate.

FIG. 1 is a cross-sectional view showing a general display device.

As shown in FIG. 1, the light emitting device 50 is assembled into the assembly hole 3 of the partition wall 2 on the substrate 1 using a self-assembly process.

During self-assembly, the light emitting device 5 is moved to the assembly hole 3 by a magnetic field from a magnet, and the light emitting device 5 is assembled in the assembly hole 3 by a dielectrophoresis force.

A plurality of assembly holes 3 are formed in the partition wall 2. For example, a red light emitting device is assembled into the corresponding assembly hole 3, then a green light emitting device is assembled into the corresponding assembly hole 3, and finally a blue light emitting device is assembled into the corresponding assembly hole 3.

These assembly holes 3 are arranged horizontally side by side on the substrate 1, and a red light emitting device, a green light emitting device, and a blue light emitting device are assembled into each of these assembly holes 3.

In this way, since the plurality of light emitting devices 5 assembled by the self-assembly method are arranged side by side in the vertical direction, there is a limit to increasing the precision even if the size of the light emitting devices 5 is reduced.

Typically, virtual reality (VR: Virtual Reality) or augmented reality (AR: Augmented Reality)-based displays require a high resolution of 3,500 PPI. However, light emitting device substrate displays using self-assembly methods cannot achieve such high precision.

Meanwhile, there has been an attempt to implement a light emitting device-based display using the PDMS stamping transfer method. However, in the case of this stamping transfer method, there is a problem that the transfer tolerance is +3 μm or more, and the tolerance of +1 μm or less required for high precision of 3,500 PPI is not satisfied.

Meanwhile, the size of the light emitting device is reduced to implement high definition or high resolution. Even if the size of each of the light emitting devices 5 arranged side by side in the horizontal direction is reduced, there is a limit to realizing high precision or high resolution, and when the size of the light emitting devices 5 is reduced, there is a problem that luminance decreases due to a decrease in light efficiency.

### DISCLOSURE

### Technical Problem

The embodiment objects to solve the above-mentioned problems and other problems.

Another object of the embodiment is to provide a display device with a new structure.

Another object of the embodiment is to provide a display device with high definition and high resolution.

Another object of the embodiment is to provide a display device that may prevent luminance degradation.

The technical objects of the embodiment are not limited to those described in this item and include those that may be understood through the description of the invention.

### Technical Solution

According to one aspect of the embodiment to achieve the above or other objects, a display device may include a substrate including a plurality of pixels and a semiconductor light emitting device in each of the plurality of pixels, the substrate includes an electrode pad part, the semiconductor light emitting device includes an electrode, the electrode is disposed on the electrode pad part, and at least one of the electrode pad part or the electrode may have a texture structure.

The texture structure may have a spike shape.

The display device may include a diffusion layer on at least one of the electrode pad part or the electrode.

The substrate may include a pattern portion, and the electrode pad part may be disposed on the pattern portion.

The semiconductor light emitting device may include a first light emitting part that generates first light, a second light emitting part that generates second light, and a third light emitting part that generates third light, the first light emitting part, the second light emitting part, and the third light emitting part may have a vertically stacked structure.

The second diameter of the second light emitting part may be larger than the first diameter of the first light emitting part, and the third diameter of the third light emitting part may be larger than the second diameter of the second light emitting part.

The semiconductor light emitting device may include a first selective penetration part between the first light emitting part and the second light emitting part and a second selective penetration part between the second light emitting part and the third light emitting part.

The semiconductor light emitting device may include a first conductive layer disposed between the first light emitting part and the first selective penetration part and electrically connected to the first electrode, a second conductive layer disposed between the first selectively penetration part and the second light emitting part and electrically connected to the second electrode and a third conductive layer disposed between the second selectively penetration part and the third light emitting part and electrically connected to the third electrode.

The semiconductor light emitting device may include a porous layer on the third light emitting part and protrusions on the third light emitting part.

### Advantageous Effects

As shown in FIG. 5, the embodiment arranges a semiconductor light emitting device 150 capable of simultaneously emitting first light, second light, and third light in each of the plurality of pixels (PX), so it is possible to implement high-definition and high-resolution displays.

That is, conventionally, the first light emitting device emitting the first light, the second light emitting device emitting the second light, and the third light emitting device emitting the third light are each arranged in a sub-pixel, so that these three Images are displayed by light emitting devices. In this case, since the first light emitting device, the second light emitting device, and the third light emitting device are arranged in the horizontal direction, there is a limit to reducing the size of the pixel, making it difficult to implement a high-definition and high-resolution display. In particular, when the size of each of the first light emitting device, the second light emitting device, and the third light emitting device is reduced, the light efficiency decreases as the size decreases, thereby lowering the luminance.

In contrast, in the embodiment, a single semiconductor light emitting device 150 capable of simultaneously generating and emitting first light, second light, and third light may be disposed in each of the plurality of pixels PX. In other words, by placing only one semiconductor light emitting device (150) in a unit pixel (PX), the size of the pixel may be significantly reduced compared to the prior art, making it possible to implement a high-definition display of 3,500 PPI or more, and also to implement an ultra-high-resolution display.

In addition, the size of the semiconductor light emitting device of the embodiment is expanded by the area occupied by the first light emitting device, the second light emitting device, and the third light emitting device that are conventionally arranged horizontally side by side, so light efficiency is significantly increased and high brightness may be obtained.

The embodiment uses a room temperature bonding method, so that the electrode 1590 of the semiconductor light emitting device 150 and the electrode pad part 220 of the substrate 201 may be easily bonded at room temperature even with weak pressure. Typically, at high temperatures, the substrate is bent due to differences in thermal expansion coefficients between different substrates, making it difficult to meet the tolerance of +1 μm or less required for high precision of 3,500 PPI or more. However, in the embodiment, the bonding process is carried out at room temperature without using high temperature, thereby satisfying the tolerance of +1 μm or less, making it possible to implement a high-definition display of 3,500 PPI or more.

In the embodiment, a texture structure in the shape of a spike 227 is formed on at least one of the electrode 1590 of the semiconductor light emitting device 150 and the electrode pad part 220 of the substrate 201, so that the spike is an electrode 1590 or may diffuse through the electrode pad part 220 to form the diffusion layer 240. The surface resistance between the electrode 1590 of the semiconductor light emitting device 150 and the electrode pad part 220 of the substrate 201 is reduced by the diffusion layer 240, the physical adhesion between the electrode 1590 of the semiconductor light emitting device 150 and the electrode pad part 220 of the substrate 201 is strengthened, and a defective electrical connection between the electrode 1590 of the semiconductor light emitting device 150 and the electrode pad part 220 of the substrate 201 may be prevented. In addition, the electrode pad part 220 of the substrate 201 is electrically connected to the metal on the surface of the electrode 1590 of the semiconductor light emitting device 150, rather than the oxidation prevention film, by the diffusion layer 240, so contact resistance is greatly reduced, smoothing voltage and current supply, and luminance may be improved through improved light efficiency.

Additional scope of applicability of the embodiment will become apparent from the detailed description below. However, since various changes and modifications within the spirit and scope of the embodiments may be clearly understood by those skilled in the art, the detailed description and specific embodiments, such as preferred embodiments, should be understood as being given by way of example only.

### DESCRIPTION OF DRAWINGS

FIG. 1 is a cross-sectional view showing a general display device.

FIG. 2 shows a living room of a house where a display device according to an embodiment is placed.

FIG. 3 is a block diagram schematically showing a display device according to an embodiment.

FIG. 4 is an enlarged view of the first panel area in the display device of FIG. 2.

FIG. 5 is a cross-sectional view showing a display device according to the first embodiment.

FIG. 6 is a perspective view showing a semiconductor light emitting device manufactured on a substrate.

FIG. 7 is a cross-sectional view of the semiconductor light emitting device of FIG. 6 taken along line A-D.

FIG. 8 is a cross-sectional view of the semiconductor light emitting device of FIG. taken along line B-D.

FIG. 9 is a cross-sectional view of the semiconductor light emitting device of FIG. 6 taken along line C-D.

FIGS. 10 and 11 show the process of manufacturing a display device by transferring the semiconductor light emitting device of FIG. 6 onto a substrate.

FIG. 12 is a plan view showing the semiconductor light emitting device of FIG. 10.

FIG. 13 is a plan view showing the substrate of FIG. 11.

FIGS. 14 to 18 explain a method of manufacturing the semiconductor light emitting device of FIG. 6.

FIG. 19 shows the wavelength bands of each of the first light, second light, and third light.

FIG. 20 shows the progress of first light, second light, and third light in the display device according to the first embodiment.

FIG. 21 shows light being selectively transmitted/blocked at the second selective penetration part.

FIG. 22 shows light being selectively transmitted/blocked at the first selective penetration part.

FIG. 23 is a cross-sectional view showing a display device according to a second embodiment.

The size, shape, and dimensions of the components shown in the drawings may differ from the actual ones. In addition, although the same components are shown in different sizes, shapes, and numbers between drawings, this is only an example in the drawings, identical components may have the same size, shape, and numerical value between drawings.

### MODE FOR INVENTION

Hereinafter, the embodiment disclosed in this specification will be described in detail with reference to the attached drawings, but identical or similar components will be assigned the same reference numerals regardless of the reference numerals, and overlapping descriptions thereof will be omitted. The suffixes ‘module’ and ‘part’ for components used in the following description are given or used interchangeably in consideration of ease of specification preparation, and do not have distinct meanings or roles in themselves. In addition, the attached drawings are intended to facilitate understanding of the embodiments disclosed in this specification, and the technical ideas disclosed in this specification are not limited by the attached drawings. Additionally, when an element such as a layer, region or substrate is referred to as being ‘on’ another component, this includes either directly on the other element or there may be other intermediate elements in between.

Display devices described in this specification include TVs, shines, mobile phones, smart phones, head-up displays (HUDs) for automobiles, backlight units for laptop computers, and displays for VR or AR, etc. may be included. However, the configuration according to the embodiment described in this specification may be applied to a device capable of displaying, even if it is a new product type that is developed in the future.

Hereinafter, a light emitting device according to an embodiment and a display device including the same will be described.

FIG. 2 shows a living room of a house where a display device according to an embodiment is placed.

Referring to FIG. 2, the display device 100 of the embodiment may display the status of various electronic products such as a washing machine 101, a robot vacuum cleaner 102, and an air purifier 103, and each electronic product and IoT-based communication, and may also control each electronic product based on the user's setting data.

The display device 100 according to the embodiment may include a flexible display manufactured on a thin and flexible substrate. Flexible displays may bend or curl like paper while maintaining the characteristics of existing flat displays.

In a flexible display, visual information may be implemented by independently controlling the light emission of unit pixels arranged in a matrix form. A unit pixel refers to the minimum unit for implementing one color. A unit pixel of a flexible display may be implemented by a light emitting device. In the embodiment, the light emitting device may be Micro-LED or Nano-LED, but is not limited thereto.

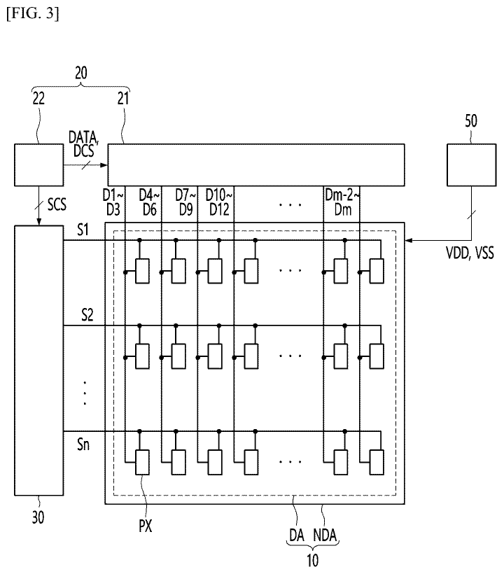

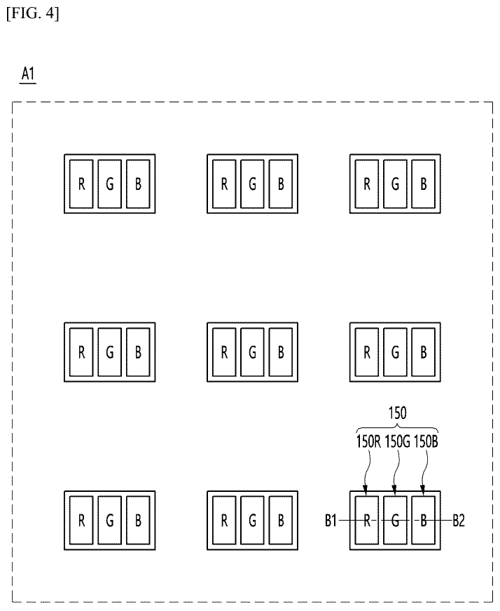

FIG. 3 is a block diagram schematically showing a display device according to an embodiment, and FIG. 4 is a circuit diagram showing an example of the pixel of FIG. 3.

Referring to FIGS. 3 and 4, a display device according to an embodiment may include a display panel 10, a driving circuit 20, a scan driver 30, and a power supply circuit 50.

The display device 100 of the embodiment may drive a light emitting device in an active matrix (AM, Active Matrix) method or a passive matrix (PM, Passive Matrix) method.

The driving circuit 20 may include a data driver 21 and a timing control unit 22.

The display panel 10 may be rectangular, but this is not limited. That is, the display panel 10 may be formed in a circular or oval shape. At least one side of the display panel 10 may be bent to a predetermined curvature.

The display panel 10 may be divided into a display area (DA) and a non-display area (NDA) disposed around the display area (DA). The display area DA is an area where pixels PX are formed to display an image. The display panel 10 includes data lines (D1 to Dm, m is an integer of 2 or more), scan lines (S1 to Sn, n is an integer of 2 or more) crossing the data lines (D1 to Dm), a high potential voltage line (VDDL) to which a high potential voltage is supplied, pixels (PX) connected to the low-potential voltage line (VSSL) and data lines (D1 to Dm) and scan lines (S1 to Sn) to which low-potential voltage is supplied.

A unit pixel (PX) includes one semiconductor light emitting device, and one scan line and three data lines are electrically connected to one semiconductor light emitting device. According to the embodiment, one semiconductor light emitting device may generate three different color lights. For example, a corresponding unit pixel (PX) is selected by a scan signal supplied to one scan line, and a data voltage is simultaneously supplied to each of the three data lines. In this case, the first color light of the first main wavelength is emitted by the first data voltage supplied to the first data line D1, the second color light of the second main wavelength is emitted by the second data voltage supplied to the second data line D2, and the third color light of the third main wavelength is emitted by the third data voltage supplied to the third data line D3. A third color light may be emitted. The first color light may be red light, the second color light may be green light, and the third color light may be blue light, but are not limited thereto.

The driving circuit 20 outputs signals and voltages for driving the display panel 10. To this end, the driving circuit 20 may include a data driver 21 and a timing control unit 22.

The data driver 21 receives digital video data (DATA) and source control signal (DCS) from the timing control unit 22. The data driver 21 converts digital video data (DATA) into analog data voltages according to the source control signal (DCS) and supplies them to the data lines (D1 to Dm) of the display panel 10.

The timing control unit 22 receives digital video data (DATA) and timing signals from the host system. Timing signals may include a vertical sync signal, a horizontal sync signal, a data enable signal, and a dot clock. The host system may be an application processor in a smartphone or tablet PC, a monitor, or a system-on-chip in a TV.

The timing control unit 22 generates control signals to control the operation timing of the data driver 21 and the scan driver 30. The control signals may include a source control signal (DCS) for controlling the operation timing of the data driver 21 and a scan control signal (SCS) for controlling the operation timing of the scan driver 30.

The driving circuit 20 may be disposed in the non-display area (NDA) provided on one side of the display panel 10. The driving circuit 20 may be formed as an integrated circuit (IC) and mounted on the display panel 10 using a chip on glass (COG) method, a chip on plastic (COP) method, or an ultrasonic bonding method. The present invention is not limited to this. For example, the driving circuit 20 may be mounted on a circuit board (not shown) rather than on the display panel 10.

The data driver 21 is mounted on the display panel 10 using a COG (chip on glass) method, a COP (chip on plastic) method, or an ultrasonic bonding method, and the timing control unit 22 is mounted on a circuit board.

The scan driver 30 receives a scan control signal (SCS) from the timing control unit 22. The scan driver 30 generates scan signals according to the scan control signal SCS and supplies them to the scan lines S1 to Sn of the display panel 10. The scan driver 30 may include a plurality of transistors and may be formed in the non-display area NDA of the display panel 10. Alternatively, the scan driver 30 may be formed as an integrated circuit, and in this case, it may be mounted on a gate flexible film attached to the other side of the display panel 10.

The circuit board may be attached to pads provided at one edge of the display panel 10 using an anisotropic conductive film. Because of this, the lead lines of the circuit board may be electrically connected to the pads. The circuit board may be a flexible printed circuit board, a printed circuit board, or a flexible film such as a chip on film. The circuit board may be bent toward the bottom of the display panel 10. Because of this, one side of the circuit board is attached to one edge of the display panel 10, and the other side is placed below the display panel 10 and may be connected to a system board on which the host system is mounted.

The power supply circuit 50 may generate voltages necessary for driving the display panel 10 from the main power supplied from the system board and supply them to the display panel 10. For example, the power supply circuit 50 generates a high-potential voltage (VDD) and a low-potential voltage (VSS) for driving the light emitting devices (LD) of the display panel 10 from the main power supply, thereby generating the display panel 10 may be supplied to the high potential voltage line (VDDL) and low potential voltage line (VSSL). Additionally, the power supply circuit 50 may generate and supply driving voltages for driving the driving circuit 20 and the scan driver 30 from the main power source.

FIG. 4 is an enlarged view of the first panel area in the display device of FIG. 3.

Referring to FIG. 4, the display device 100 of the embodiment may be manufactured by mechanically and electrically connecting a plurality of panel areas, such as the first panel area A1, by tiling.

The first panel area A1 may include a semiconductor light emitting device 150 arranged for each unit pixel (PX in FIG. 3). The semiconductor light emitting device 150 may emit red light, green light, and blue light at the same time.

Meanwhile, the embodiment may implement a high-definition and high-resolution display by disposing a single semiconductor light emitting device that simultaneously emits first light, second light, and third light in each pixel.

Descriptions omitted below may be easily understood from FIGS. 4 to 9 and the description given above in relation to the corresponding drawings.

### First Embodiment

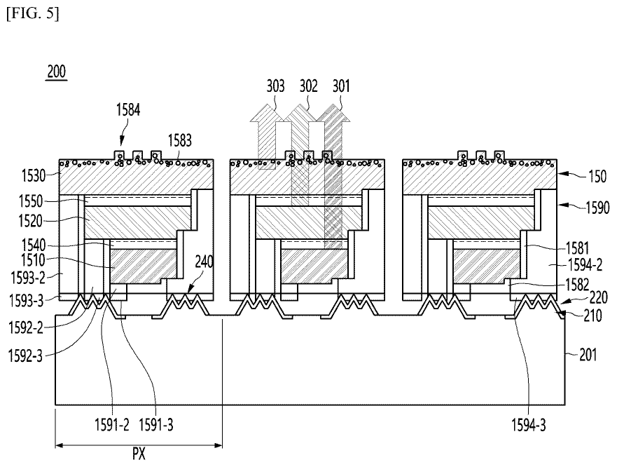

FIG. 5 is a cross-sectional view showing a display device according to the first embodiment.

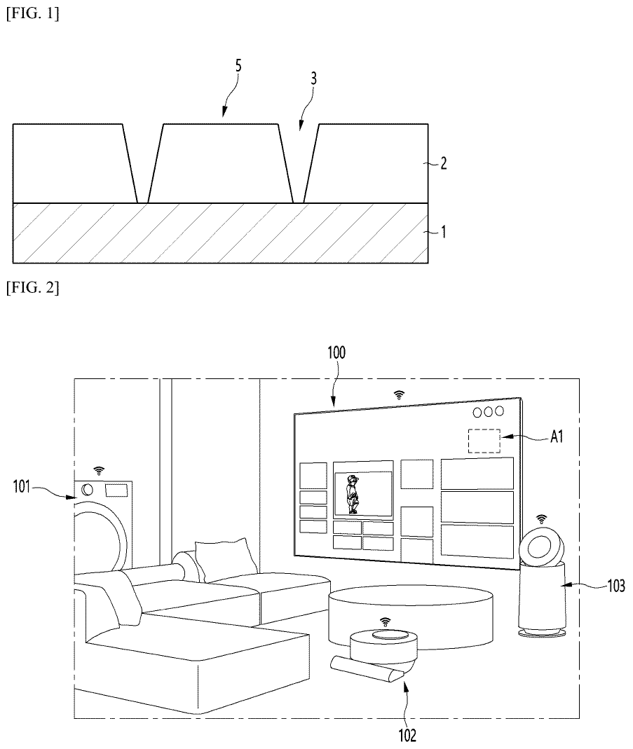

Referring to FIG. 1, the display device 200 according to the first embodiment may include a substrate 201 and a semiconductor light emitting device 150.

The substrate 201 may be a support member that supports components placed on the substrate 201 or a protection member that protects the components.

The substrate 201 may be a rigid substrate or a flexible substrate. The substrate 201 may be formed of sapphire, glass, silicon, or polyimide. Additionally, the substrate 201 may include a flexible material such as PEN (Polyethylene Naphthalate) or PET (Polyethylene Terephthalate). Additionally, the substrate 201 may be a transparent material, but is not limited thereto.

The substrate 201 may be a backplane equipped with a driver (not shown) for driving the semiconductor light emitting device 150, but this is not limited. The driver may include circuits, such as transistors (ST, DT), capacitors (Cst), signal wires, etc.

The substrate 201 may include a plurality of pixels (PX). Each of the plurality of pixels (PX) may emit first light 301, second light 302, and third light 303.

For this purpose, a semiconductor light emitting device 150 may be disposed in each of the plurality of pixels (PX).

According to the first embodiment, a semiconductor light emitting device 150 may be physically attached to the substrate 201 and electrically connected to each of the plurality of pixels (PX).

For this purpose, the substrate 201 may include an electrode pad part 220. The semiconductor light emitting device 150 may include an electrode 1590.

The electrode pad part 220 may have a texture structure. For example, the texture structure may have a spike shape 227. The spike shape 227 may be composed of a peak as a mountain and a bottom as a valley.

The electrode 1590 of the semiconductor light emitting device 150 may be disposed on the electrode pad part 220 of the substrate 201.

Typically, in order to obtain high precision, the electrode of the semiconductor light emitting device and the electrode pad part of the substrate are to be bonded, taking into account the thermal expansion coefficient between different substrates. If bonding is carried out by applying high temperature heat, the substrate equipped with the electrode pad part is bent. Accordingly, it is difficult to obtain high resolution because the pixels are to be designed to meet tolerances that take into account the bending of the substrate.

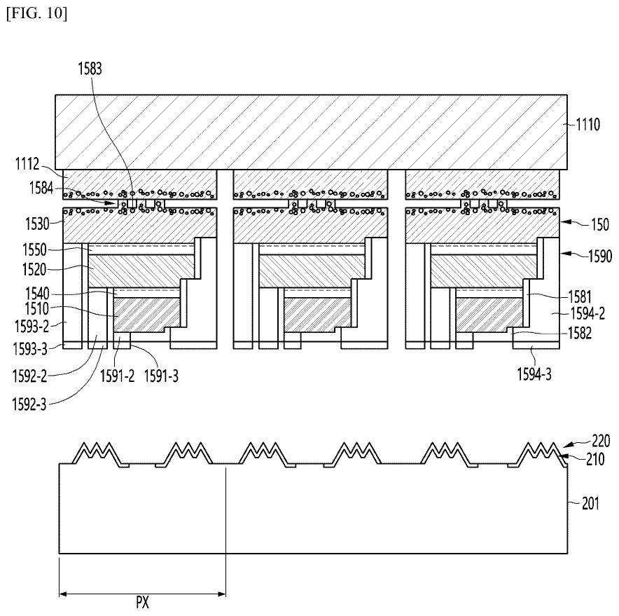

However, according to the embodiment, a plurality of patterns (protrusions (in the final product) spaced apart from each other are formed between the substrate (1110 in FIG. 10) used to manufacture the semiconductor light emitting device 150 and the semiconductor light emitting device 150. By the formation of (existing as 1584) in FIG. 5, even if the thermal expansion coefficients between the heterogeneous substrates 1110 and 201 are different, the plurality of semiconductor devices 150 are uniformly pressed onto the substrate 201, so that high precision may be obtained and bonding defects may be prevented.

Conventionally, a plurality of semiconductor light emitting devices manufactured on a substrate are transferred to a donor substrate (or temporary substrate), it was difficult to achieve high precision by transferring multiple light emitting devices on the temporary substrate to the display substrate, and transferring them twice.

However, according to the embodiment, the electrode pad part 220 of the substrate 201 and the electrode 1590 of the semiconductor light emitting device 150 may be bonded using a room temperature bonding method. The room temperature bonding method may be a method of bonding the semiconductor light emitting device 150 of the substrate 1110 to the electrode pad part 220 of the substrate 201 at room temperature. Room temperature may be, for example, a temperature between 15 degrees and 30 degrees. Since direct bonding is performed between the substrates 1110, 201 using a room temperature bonding method, a high-definition display of 3,500 PPI or more may be implemented.

In order to easily realize the room temperature bonding method, the electrode pad part 220 of the substrate 201 and the electrode 1590 of the semiconductor light emitting device 150 may contain gold (Au), but is not limited to this.

For example, when the semiconductor light emitting device 150 is pressurized at room temperature, due to the spike shape 227 of the electrode pad part 220 of the substrate 201, the electrode pad part 220 of the substrate 201) may penetrate into the electrode 1590 of the semiconductor light emitting device 150 to form a diffusion layer 240 within the electrode 1590. When the electrode pad part 220 of the substrate 201 and the electrode 1590 of the semiconductor light emitting device 150 contain gold (Au), even if a small pressure is applied to the electrode 1590 of the semiconductor light emitting device 150, the spikes of the electrode pad part 220 of the substrate 201 may easily penetrate the surface of the electrode 1590 of the semiconductor light emitting device 150 and diffuse into the surface, thereby forming the diffusion layer 240. In addition, since the surface of the electrode pad part 220 of the substrate 201 is formed of spike-shaped gold (Au), room temperature bonding is possible without voids.

The diffusion layer 240 reduces the surface resistance between the electrode 1590 of the semiconductor light emitting device 150 and the electrode pad part 220 of the substrate 201, may strengthens the physical adhesion between the electrode 1590 of the semiconductor light emitting device 150 and the electrode pad part 220 of the substrate 201, and may prevent electrical connection failure between the electrode 1590 of the semiconductor light emitting device 150 and the electrode pad part 220 of the substrate 201.

Typically, the electrode of a semiconductor light emitting device or the electrode pad part of the substrate is oxidized when exposed to air, forming an oxidation prevention film with high resistance on the surface. In this case, since the oxidation prevention film formed on the surface of the electrode of the semiconductor light emitting device and the oxidation prevention film formed on the surface of the electrode pad part of the substrate are in surface contact, the electrical resistance may increase significantly, making voltage or current supply difficult.

However, as in the embodiment, the spike of the electrode pad part 220 of the substrate 201 penetrates the anti-oxidation film formed on the surface of the electrode 1590 of the semiconductor light emitting device 150 and diffuses or penetrates into it to form the diffusion layer 240. Therefore, as the electrode pad part 220 of the substrate 201 is electrically connected to the metal in the surface of the electrode 1590 of the semiconductor light emitting device 150, rather than the oxidation prevention film, by the diffusion layer 240, by greatly reducing contact resistance, voltage and current supply may be smoothly supplied, and brightness may be improved through improved light efficiency.

On the other hand, if the surface of the electrode of the semiconductor light emitting device or the electrode pad part of the substrate is contaminated, room temperature bonding without voids is difficult. Therefore, for void-free room temperature bonding, it is necessary to remove contaminants from the surface of the electrode of the semiconductor light emitting device or the electrode pad part of the substrate.

According to the embodiment, contaminants on the surface of the electrode 1590 of the semiconductor light emitting device 150 or the electrode pad part 220 of the substrate 201 may be removed through ultrasonic vibration or plasma cleaning.

Meanwhile, the substrate 201 may include a pattern portion 210. In this case, the electrode pad part 220 may be disposed on the pattern portion 210. For example, the pattern portion 210 may be the same or larger than the size of the electrode 1590 of the semiconductor light emitting device 150, but this is not limited. The surface (or top surface) of the pattern portion 210 may have a texture structure. For example, the pattern portion 210 may be formed of an insulating material.

The surface of the electrode pad part 220 may have a shape corresponding to the shape of the surface of the pattern portion 210. That is, the height of the peak or the depth of the valley in the texture structure of the electrode pad part 220 may be determined by the shape of the texture structure formed on the surface of the pattern portion 210.

Meanwhile, the semiconductor light emitting device 150 may include a first light emitting part 1510, a second light emitting part 1520, and a third light emitting part 1530. The first light emitting part 1510, the second light emitting part 1520, and the third light emitting part 1530 may have a vertically stacked structure.

The first light emitting part 1510 generates the first light 301, the second light emitting part 1520 generates the second light 302, and the third light emitting part 1530 may generate third light 303. For example, as shown in FIG. 19, the first light 301 includes red light corresponding to the red wavelength band, the second light 302 may include green light corresponding to the green wavelength band, and the third light 303 may include blue light corresponding to the blue wavelength band, but is not limited thereto.

Therefore, the first light 301 generated in the first light emitting part 1510, the second light 302 generated in the second light emitting part 1520, and the third light emitting part 1530 generated in third light 303 may be emitted to the outside through the third light emitting part 1530. A full color image may be implemented by the first light 301, second light 302, and third light 303 emitted to the outside.

Typically, a light emitting part that generates light with a large wavelength is excited by light with a short wavelength, and the light emitting part may emit light with a short wavelength as well as light with a large wavelength.

To solve this problem, in the case of the top emission method in which the light 301, 302, 303 is emitted in the upward direction, the second light emitting part 1520 is disposed on the first light emitting part 1510 And, the third light emitting part 1530 may be disposed on the second light emitting part 1520. For example, the second light emitting part 1520 vertically overlaps the first light emitting part 1510, the third light emitting part 1530 may vertically overlap each of the first light emitting part 1510 and the second light emitting part 1520.

As described above, the third light 303 generated from the third light emitting part 1530, that is, the wavelength of blue light, is the wavelength of the first light 301 of the first light emitting part 1510 or the third light emitting part 1530. Since it is shorter than the wavelength of the second light 302 of the second light emitting part 1520, the third light emitting part 1530 may be disposed on the first light emitting part 1510 or the second light emitting part 1520. In this case, the wavelength of the first light 301 of the first light emitting part 1510 or the wavelength of the second light 302 of the second light emitting part 1520 is the third light emitting part 1530. Since it is longer than the wavelength of light 303, even if the first light 301 of the first light emitting part 1510 or the second light 302 of the second light emitting part 1520 passes through the third light emitting part 1530, the third light emitting part 1530 may not be excited by the first light 301 or the second light 302. Therefore, even if the first light 301 of the first light emitting part 1510 or the second light 302 of the second light emitting part 1520 passes through the third light emitting part 1530, the third light emitting part 1530 part 1530 may only generate third light 303.

As the second light 302 generated from the second light emitting part 1520, that is, the wavelength of the green light is longer than the wavelength of the third light 303 of the third light emitting part 1530 and shorter than the wavelength of the first light 301 of the first light emitting part 1510, the second light emitting part 1520 may be disposed between the first light emitting part 1510 and the third light emitting part 1530. In this case, the wavelength of the first light 301 of the first light emitting part 1510 is longer than the wavelength of the second light 302 of the second light emitting part 1520 or the third light 303 of the third light emitting part 1530, even if the first light 301 of the first light emitting part 1510 passes through the second light emitting part 1520 or the third light emitting part 1530, the second light emitting part 1520 or the third light emitting part 1530 may not be excited by the first light 301. Therefore, even if the first light 301 of the first light emitting part 1510 passes through the second light emitting part 1520 or the third light emitting part 1530, the second light emitting part 1520 may generate only the second light 302 and the third light emitting part 1530 may generate only the third light 303.

Meanwhile, the first light 301 generated by the first light emitting part 1510, the second light 302 generated by the second light emitting part 1520, and the third light 303 generated from the third light emitting part 1530 radiates in all directions, the first light 301, the second light 302 and the third light 303 may travel not only in the upward direction but also in the downward direction.

As described above, since the wavelengths of the first light 301, the second light 302, and the third light 303 are short in that order, when each of the first light 301, the second light 302, and the third light 303 travels upward, a color mixing problem does not occur.

However, when each of the first light 301, the second light 302, and the third light 303 travels downward, a color mixing problem occurs. That is, when the third light 303 travels downward and is incident on the second light emitting part 1520 or the first light emitting part 1510, the second light emitting part 1520 or the first light emitting part 1510 may be excited by the third light 303, and the third light 303 may be generated in the second light emitting part 1520 or the first light emitting part 1510. In this case, the second light emitting part 1520 generates not only the second light 302 but also the third light 303, the first light emitting part 1510 generates not only the first light 301 but also the third light 303, so a color mixing problem may occur.

To solve this problem, the semiconductor light emitting device 150 may include a first optional penetration part 1540 and a second optional penetration part 1550.

The first optional penetration part 1540 may be disposed between the first light emitting part 1510 and the second light emitting part 1520. The second optional penetration part 1550 may be disposed between the second light emitting part 1520 and the third light emitting part 1530. For example, the first optional penetration part 1540 and the second optional penetration part 1550 may have a distributed Bragg reflector (DBR) structure. The DBR structure may be formed by stacking media layers with different refractive indices. These media layers may be made of an inorganic insulating material. For example, the first medium layer to be stacked may include SiO2, and the second medium layer may include TiO2, but is not limited to this.

The first optional penetration part 1540 may be called a first filter, and the second optional penetration part 1550 may be called a second filter.

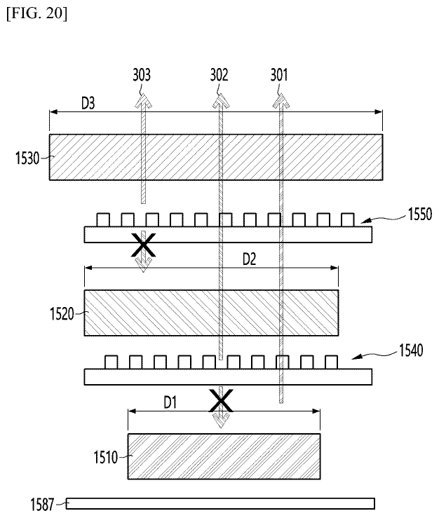

As shown in FIG. 20, the first optional penetration part 1540 may transmit the first light 301 and reflect the second light 302. The second optional penetration part 1550 may transmit the first light 301 or the second light 302 and reflect the third light 303.

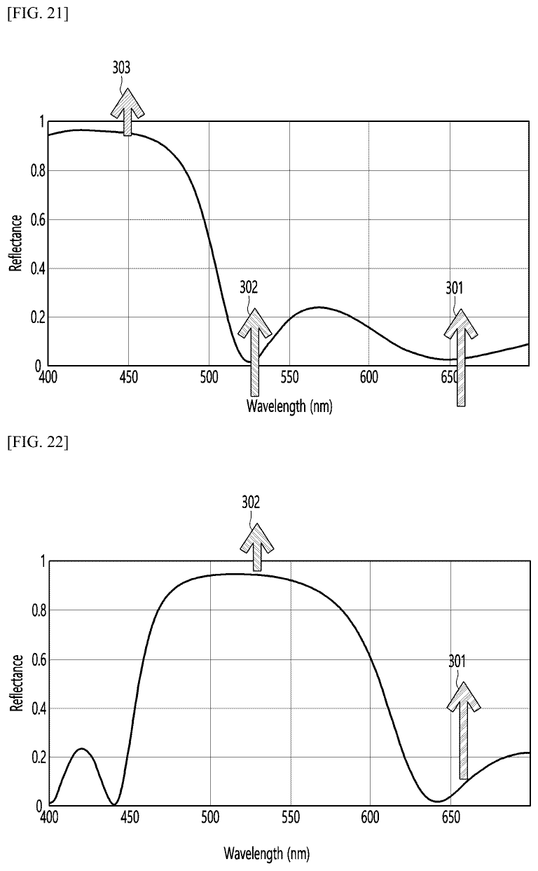

As shown in FIG. 21, the reflectivity of the first selective penetration part 1540 for the first light 301 is close to 0, while the reflectivity for the second light 302 is close to 1. As the reflectivity approaches 0, the reflectance of light approaches 0% and the transmittance approaches 100%. As the reflectivity approaches 1, the reflectance of light approaches 100% and the transmittance approaches 0%. Accordingly, the first light 301 may pass through the first selective penetration part 1540 and be emitted to the outside, but the second light 302 is reflected by the first selective penetration part 1540 and does not enter the first light emitting part 1510. Therefore, the second light 302 of the second light emitting part 1520 is incident on the first light emitting part 1510 and not only the first light 301 but also the second light 302 is generated in the first light emitting part 1510, the light mixing defects that occur may be prevented.

As shown in FIG. 22, while the reflectivity of the second selective penetration part 1550 to the first light 301 or the second light 302 is close to 0, the reflectivity for the third light 303 is close to 1. As the reflectivity approaches 0, the reflectance of light approaches 0% and the transmittance approaches 100%. As the reflectivity approaches 1, the reflectance of light approaches 100% and the transmittance approaches 0%. Accordingly, the first light 301 or the second light 302 may pass through the second selective penetration part 1550 and be emitted to the outside, but the third light 303 is reflected by the second selective penetration part 1550 and does not enter the second light emitting part 1520. Therefore, the third light 303 of the third light emitting part 1530 is incident on the second light emitting part 1520, and not only the second light 302 but also the third light 303 is also generated, thereby preventing light mixing defects.

Meanwhile, as shown in FIG. 20, a reflective layer 1587 may be disposed below the first light emitting part 1510. For example, the reflective layer 1587 may be provided in the semiconductor light emitting device 150. For example, the reflective layer 1587 may be disposed between the first light emitting part 1510 and the second insulating layer 1582. For example, the reflective layer 1587 may be included in the electrode 1590. For example, the reflective layer 1587 may be provided on the substrate 201. The reflective layer 1587 reflects the first light 301 generated by the first light emitting part 1510 and allows it to be emitted to the outside, thereby improving light efficiency.

On the other hand, the amount of green light and blue light is usually less than that of red light, so luminance unevenness between color lights may occur. To solve this problem, the second diameter D2 of the second light emitting part 1520 is larger than the first diameter D1 of the first light emitting part 1510, and the third diameter D3 of the third light emitting part 1530 may be larger than the second diameter D2 of the second light emitting part 1520. Therefore, the second diameter D2 of the second light emitting part 1520 that generates the second light 302, that is, green light, or the third light emitting part D2 that generates the third light 303, that is, blue light, 1530) by designing the third diameter D3 to be larger than the first diameter D1 of the first light 301, that is, the first light emitting part 1510 that generates red light, it is possible to prevent luminance non-uniformity defects between color lights.

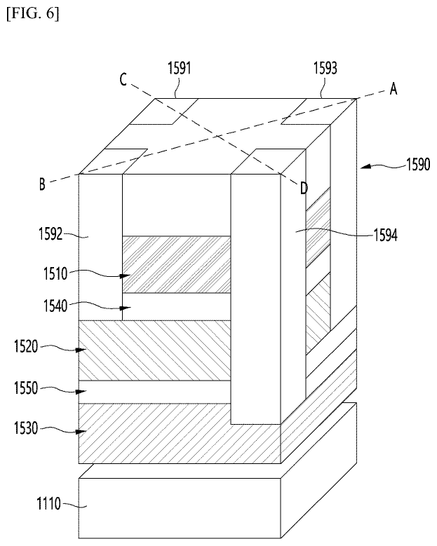

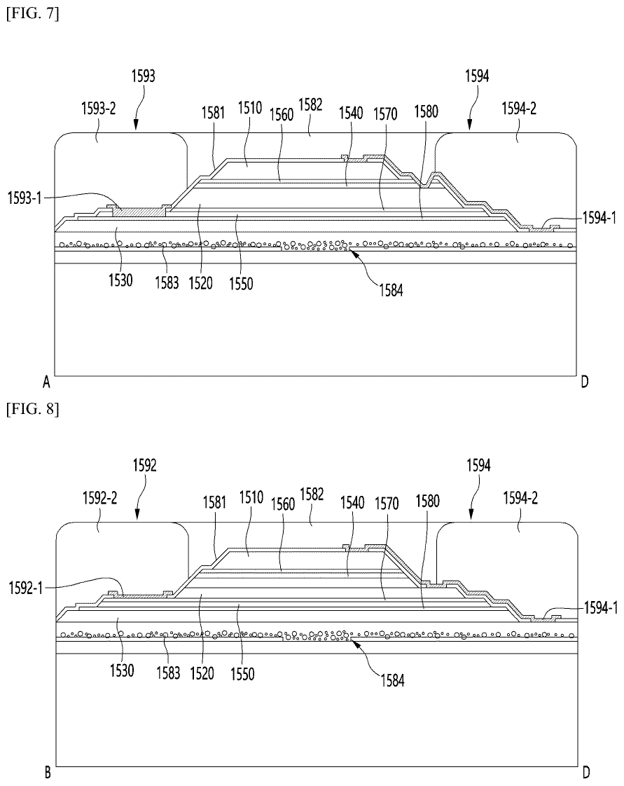

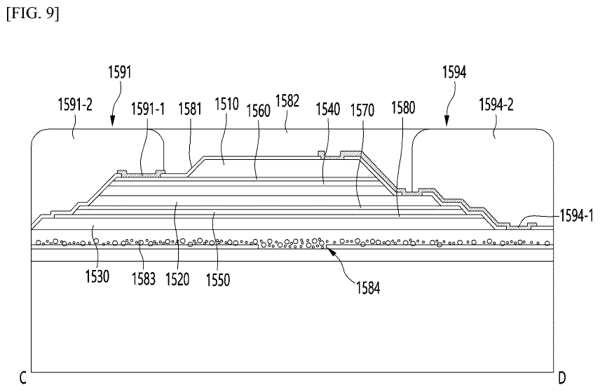

The structure of the semiconductor light emitting device will be described in more detail with reference to FIGS. 6 to 9. FIG. 6 is a perspective view showing a semiconductor light emitting device manufactured on a substrate. FIG. 7 is a cross-sectional view of the semiconductor light emitting device of FIG. 6 taken along line A-D. FIG. 8 is a cross-sectional view of the semiconductor light emitting device of FIG. 6 taken along line B-D. FIG. 9 is a cross-sectional view of the semiconductor light emitting device of FIG. 6 taken along line C-D. The structure of the semiconductor light emitting device 150 shown in FIGS. 6 to 9 is only an example, and various structural modifications are possible.

As shown in FIG. 6, a semiconductor light emitting device 150 may be manufactured on the substrate 1110. After the semiconductor light emitting device 150 is transferred to the substrate 201, that is, a display substrate, the substrate 1110 may be separated and removed. The substrate 1110 may be a semiconductor wafer.

The semiconductor light emitting device 150 may be manufactured on the substrate 1110. The semiconductor light emitting device 150 may have a structure capable of simultaneously generating first light 301, second light 302, and third light 303.

When the semiconductor light emitting device 150 is transferred to the substrate 201, the third light emitting part 1530, the second light emitting part 1520, and the first light emitting part 1510 of the semiconductor light emitting device 150 may be sequentially arranged on the substrate 201. That is, the second light emitting part 1520 may be placed on the third light emitting part 1530, and the first light emitting part 1510 may be placed on the second light emitting part 1520. The first light emitting part 1510, the second light emitting part 1520, and the third light emitting part 1530 may have a mesa structure, but is not limited to this.

The first light emitting part 1510, the second light emitting part 1520, and the third light emitting part 1530 may each include at least one first conductivity-type semiconductor layer, an active layer, and at least one second conductivity-type semiconductor layer. For example, the first conductivity type dopant may be an n-type dopant, and the second conductivity type dopant may be a p-type dopant, but is not limited to this.

The semiconductor light emitting device 150 may include a second optional penetration part 1550 between the third light emitting part 1530 and the second light emitting part 1520 and a first optional penetration part 1540 between the second light emitting part 1520 and the first light emitting part 1510.

The semiconductor light emitting device 150 may include a first conductive layer 1560, a second conductive layer 1570, and a third conductive layer 1580. The first conductive layer 1560, the second conductive layer 1570, and the third conductive layer 1580 may be made of a transparent conductive material. For example, the first conductive layer 1560, the second conductive layer 1570, and the third conductive layer 1580 may include ITO, IZO, or the like.

Since the thickness of the second conductivity-type semiconductor layer containing a p-type dopant is much thinner than the thickness of the first conductivity-type semiconductor layer containing an n-type dopant, the number of holes generated in the second conductivity-type semiconductor layer is much smaller than the number of electrons generated in the first conductivity-type semiconductor layer. This causes a decrease in the amount of light in the active layer.

Each of the first conductive layer 1560, the second conductive layer 1570, and the third conductive layer 1580 may increase the number of holes in the second conductivity-type semiconductor layer through a current spreading effect.

The first conductive layer 1560 may be disposed between the first light emitting part 1510 and the first selective penetration part 1540. For example, the first conductive layer 1560 is in contact with the second conductivity-type semiconductor layer of the first light emitting part 1510, the number of holes may be increased by spreading current over the entire area of the second conductivity-type semiconductor layer of the first light emitting part 1510.

The second conductive layer 1570 may be disposed between the second light emitting part 1520 and the second optional penetration part 1550. For example, the second conductive layer 1570 is in contact with the second conductivity-type semiconductor layer of the second light emitting part 1520, the number of holes may be increased by spreading current over the entire area of the second conductivity-type semiconductor layer of the second light emitting part 1520.

The third conductive layer 1580 may be disposed between the second optional penetration part 1550 and the third light emitting part 1530. For example, the third conductive layer 1580 is in contact with the second conductivity-type semiconductor layer of the third light emitting part 1530, the number of holes may be increased by spreading current over the entire area of the second conductivity-type semiconductor layer of the third light emitting part 1530.

The second conductivity-type semiconductor layer of the second light emitting part 1520 and the second conductivity-type semiconductor layer of the third light emitting part 1530 may be arranged to face each other.

Meanwhile, the semiconductor light emitting device 150 may include an electrode 1590.

The electrode 1590 may include a first electrode 1591, a second electrode 1592, a third electrode 1593, and a fourth electrode 1594.

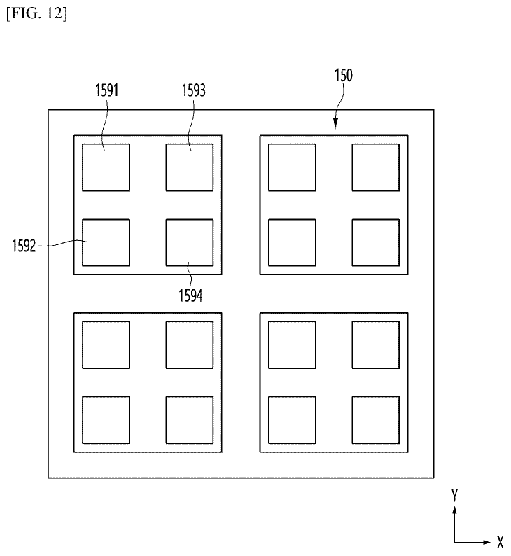

As shown in FIG. 12, the first electrode 1591, the second electrode 1592, the third electrode 1593, and the fourth electrode 1594 may be arranged to be spaced apart from each other. The first electrode 1591, the second electrode 1592, the third electrode 1593, and the fourth electrode 1594 may have a grid shape, but this is not limited. The first electrode 1591 and the second electrode 1592 are disposed along the second direction (Y), the first electrode 1591 and the third electrode 1593 may be arranged along the first direction (X), and the first electrode 1591 and the fourth electrode 1594 may be arranged along the diagonal direction.

The first electrode 1591 may be disposed on the first side of the first light emitting part 1510, that is, on one area of the first conductive layer 1560. For example, the first electrode 1591 may be electrically connected to one region of the first conductive layer 1560. The second electrode 1592 may be disposed on the first side of the second light emitting part 1520, that is, on one area of the second conductive layer 1570. For example, the second electrode 1592 may be electrically connected to one region of the second conductive layer 1570. The third electrode 1593 may be disposed on the first side of the third light emitting part 1530, that is, on one area of the third conductive layer 1580. For example, the third electrode 1593 may be electrically connected to one region of the third conductive layer 1580.

The fourth electrode 1594 may be disposed on the second side of each of the first light emitting part 1510, the second light emitting part 1520, and the third light emitting part 1530. For example, the fourth electrode 1594 may be electrically connected to a region of the first conductivity-type semiconductor layer of the first light emitting part 1510, a region of the first conductivity-type semiconductor layer of the second light emitting part 1520 and to a region of each of the first conductivity-type semiconductor layer of the third light emitting part 1530. The fourth electrode 1594 may be a common electrode commonly connected to the first light emitting part 1510, the second light emitting part 1520, and the third light emitting part 1530. For example, the fourth electrode 1594 may be grounded, but this is not limited.

Meanwhile, the first electrode 1591, the second electrode 1592, the third electrode 1593, and the fourth electrode 1594 may have different lengths. Here, the length may mean the length in the vertical direction. For example, this is to make the protruding lengths of each of the first electrode 1591, the second electrode 1592, the third electrode 1593, and the fourth electrode 1594 the same. The protruding lengths of the first electrode 1591, the second electrode 1592, the third electrode 1593, and the fourth electrode 1594 are to be the same, the semiconductor light emitting device 150 may be bonded to the substrate 201 without being tilted.

The lengths of the first electrode 1591, the second electrode 1592, the third electrode 1593, and the fourth electrode 1594 may be increased in that order. For example, the length of the second electrode 1592 connected to the first side of the second light emitting part 1520 may be greater than the length of the first electrode 1591 connected to the first side of the first light emitting part 1510. For example, the length of the third electrode 1593 connected to the first side of the third light emitting part 1530 may be longer than the length of the second electrode 1592. For example, the length of the fourth electrode 1594 commonly connected to the first light emitting part 1510, the second light emitting part 1520, and the fourth light emitting part may be greater than the length of the third electrode 1593.

Meanwhile, as shown in FIGS. 5 and 7 to 9, each of the first electrode 1591, the second electrode 1592, the third electrode 1593, and the fourth electrode 1594 may include contact electrodes 211-1, 212-1, 213-1, 214-1, connection electrodes 211-2, 212-2, 213-2, 214-2, and bonding electrodes 211-3, 212-3, 213-3, 214-3. Contact electrodes 211-1, 212-1, 213-1, 214-1, connection electrodes 211-2, 212-2, 213-2, 214-2, and bonding electrodes 211-3, 212-3, 213-3, 214-3 may be stacked vertically.

In the first electrode 1591, the contact electrode 211-1 is electrically connected to the first conductive layer 1560, the connection electrode 211-2 is in contact with the contact electrode 211-1, and the bonding electrode 211-3 is in contact with the connection electrode 211-2 and may be exposed to the outside. In the second electrode 1592, the contact electrode 212-1 is electrically connected to the second conductive layer 1570, the connection electrode 212-2 is in contact with the contact electrode 212-1, and the bonding electrode 212-3 is in contact with the connection electrode 212-2 and may be exposed to the outside.

In the third electrode 1593, the contact electrode 213-1 is electrically connected to the third conductive layer 1580, the connection electrode 213-2 is in contact with the contact electrode 213-1, and the bonding electrode 214-3 is in contact with the connection electrode 213-2 and may be exposed to the outside. In the fourth electrode 1594, the contact electrode 214-1 may be commonly connected to the first conductivity-type semiconductor layer of the first light emitting part 1510, the first conductivity-type semiconductor layer of the second light emitting part 1520 and the first conductivity-type semiconductor layer of the third light emitting part 1530. In the fourth electrode 1594, the connection electrode 214-2 is in contact with the contact electrode 214-1, and the bonding electrode 214-3 is in contact with the connection electrode 214-2 and may be exposed to the outside.

The connection electrode 211-2 of the first electrode 1591, the connection electrode 212-2 of the second electrode 1592, the connection electrode 213-2 of the third electrode 1593 and the connection electrode 214-2 of the fourth electrode 1594 may have different lengths in the vertical direction. By adjusting the length of each of the connection electrode 211-2 of the first electrode 1591, the connection electrode 212-2 of the second electrode 1592, the connection electrodes 213-2 of the third electrode 1593 and the connection electrode 214-2 of the fourth electrode 1594, bonding electrode 211-3 of the first electrode 1591, bonding electrode 212-3 of the second electrode 1592, the bonding electrode 213-3 of the third electrode 1593 and the bonding electrode 214-3 of the fourth electrode 1594 may be located on the same line. For example, the vertical length may increase in the order of the connection electrode 211-2 of the first electrode 1591, the connection electrode 212-2 of the second electrode 1592, and the connection electrode 213-2 of the third electrode 1593 and the connection electrode 214-2 of the fourth electrode 1594.

Meanwhile, the semiconductor light emitting device 150 may include a first insulating layer 1581 and a second insulating layer 1582.

The first insulating layer 1581 may be disposed around the first light emitting part 1510, the second light emitting part 1520, and the third light emitting part 1530. For example, the first insulating layer 1581 may be disposed on the top surface of the first light emitting part 1510 and on each side of the first light emitting part 1510, the second light emitting part 1520, and the third light emitting part 1530. The first insulating layer 1581 may prevent an electrical short circuit by insulating the first to third light emitting parts 1510, 1520, and 1530 and the first to fourth electrodes 1591, 1592, 1593, and 1594.

The second insulating layer 1582 may be disposed on the first insulating layer 1581 disposed on the top surface of the first light emitting part 1510. The second insulating layer 1582 may protect the first light emitting part 1510 from external shock, moisture, or foreign substances.

The second insulating layer 1582 may prevent the first electrode 1591, the second electrode 1592, the third electrode 1593, and the fourth electrode 1594 from protruding. That is, the first electrode 1591, the second electrode 1592, the third electrode 1593, and the fourth electrode 1594 may protrude in a vertical direction with respect to the first light emitting part 1510. In this case, the second insulating layer 1582 may be disposed between the first electrode 1591, the second electrode 1592, the third electrode 1593, and the fourth electrode 1594 that protrude in the vertical direction. For example, the top surface of each of the first electrode 1591, the second electrode 1592, the third electrode 1593, and the fourth electrode 1594 may be positioned on the same line as the top surface of the second insulating layer 1582. Therefore, since the first electrode 1591, the second electrode 1592, the third electrode 1593, and the fourth electrode 1594 together with the second insulating layer 1582 form a plane, when pressurized to transfer the semiconductor light emitting device 150 onto the substrate 201, the semiconductor light emitting device 150 may be stably transferred (or bonded) to the substrate 201 without being tilted.

As an example, the first insulating layer 1581 and the second insulating layer 1582 may be formed of the same material. For example, the first insulating layer 1581 and the second insulating layer 1582 may be formed of an inorganic material.

As another example, the first insulating layer 1581 and the second insulating layer 1582 may be formed of different materials. For example, the first insulating layer 1581 may be formed of an inorganic material such as SiOx or SiNx, and the second insulating layer may be formed of a resin material such as epoxy or an organic material.

Meanwhile, as described above, the substrate 201 may include a pattern portion 210.

The pattern portion 210 may be arranged to correspond to the electrode pad part 220.

As will be explained later, the electrode pad part 220 includes four electrode pads 221, 222, 223, and 224, so the pattern portion 210 may also include four patterns. The first pattern, second pattern, third pattern, and fourth pattern may be disposed on the same layer, that is, the substrate 201. Each of the first pattern, second pattern, third pattern, and fourth pattern may protrude upward from the top surface of the substrate 201. The first pattern, second pattern, third pattern, and fourth pattern may be arranged to be spaced apart from each other.

For example, the first pattern may have a first texture, the second pattern may have a second texture, the third pattern may have a third texture, and the fourth pattern may have a fourth texture. The first texture is formed on the top surface of the first pattern, the second texture is formed on the top surface of the second pattern, the third texture may be formed on the top surface of the third pattern, and the fourth texture may be formed on the top surface of the fourth pattern.

Each of the first pattern, second pattern, third pattern and fourth pattern may be provided to obtain a texture structure formed on the upper surfaces of each of the first electrode pad 221, the second electrode pad 222 of the electrode pad part 220, third electrode pad 223 and fourth electrode pad 224. That is, each of the first electrode pad 221, the second electrode pad 222, the third electrode pad 223, and the fourth electrode pad 224 of the electrode pad part 220 may be formed in a texture shape corresponding to the first texture of the first pattern, the second texture of the second pattern, the third texture of the third pattern, and the fourth texture of the fourth pattern.

When the semiconductor light emitting device 150 is transferred onto the substrate 201, the electrode 1590 of the semiconductor light emitting device 150 may be placed on the electrode pad part 220 of the substrate 201.

The electrode pad part 220 may be arranged to correspond to the electrode 1590 of the semiconductor light emitting device 150, as shown in FIGS. 12 and 13.

The electrode pad part 220 may include a first electrode pad 221, a second electrode pad 222, a third electrode pad 223, and a fourth electrode pad 224. The first electrode pad 221, the second electrode pad 222, the third electrode pad 223, and the fourth electrode pad 224 may be disposed on the same layer.

The first electrode pad 221 is disposed on the first pattern of the pattern portion 210, and the second electrode pad 222 is disposed on the second pattern of the pattern portion 210, the third electrode pad 223 may be disposed on the third pattern of the pattern portion 210, and the fourth electrode pad 224 may be disposed on the fourth pattern of the pattern portion 210. Accordingly, the first electrode pad 221 may have a texture structure corresponding to the first texture on the first pattern, and the second electrode pad 222 may have a texture structure corresponding to the second texture on the second pattern. The third electrode pad 223 may have a texture structure corresponding to the third texture on the third pattern, and the fourth electrode pad 224 may have a texture structure corresponding to the fourth texture on the fourth pattern.

The semiconductor light emitting device 150 may be disposed on the first electrode pad 221, the second electrode pad 222, the third electrode pad 223, and the fourth electrode pad 224.

For example, the first electrode 1591 of the semiconductor light emitting device 150 is disposed on the first electrode pad 221, and the second electrode 1592 of the semiconductor light emitting device 150 may be disposed on the second electrode pad 222. For example, the third electrode 1593 of the semiconductor light emitting device 150 is disposed on the third electrode pad 223, and the fourth electrode 1594 of the semiconductor light emitting device 150 may be disposed on the fourth electrode pad 224.

Referring again to FIG. 5, the semiconductor light emitting device 150 may include a porous layer 1583 and at least one protrusion 1584.

The porous layer 1583 may be disposed on the third light emitting part 1530. The porous layer 1583 may include a plurality of pores. That is, multiple pores may be distributed in the porous layer 1583. Multiple functions may have random sizes. The plurality of pores may contain air.

As an example, the porous layer 1583 may be formed integrally with the third light emitting part 1530. In this case, a plurality of pores may be crowded close to the upper surface of the third light emitting part 1530. For example, the porous layer 1583 may be distributed from the upper surface of the third light emitting part 1530 to a depth of 1/3 of the thickness of the third light emitting part 1530.

As another example, the porous layer 1583 may be formed separately from the third light emitting part 1530. That is, a porous layer 1583 may be formed on the upper surface of the third light emitting part 1530.

The first light 301 generated by the first light emitting part 1510, the second light 302 generated by the second light emitting part 1520, and the third light 303 generated by the third light emitting part 1530 silver are not trapped inside the third light emitting part 1530 but is diffused through the plurality of pores of the porous layer 1583 to minimize guide in the lateral direction, thereby improving light extraction efficiency. In addition, the first light 301, the second light 302, and the third light 303 are scattered by the plurality of pores, so that uniformly distributed light may be obtained.

The protrusions 1584 may be placed on the third light emitting part 1530. For example, protrusions 1584 may be disposed on porous layer 1583.

For example, protrusions 1584 may be part of the porous layer 1583. That is, the upper surface of the porous layer 1583 may be partially etched to form at least one protrusion 1584. Multiple pores may be distributed in protrusions 1584.

When the porous layer 1583 and/or protrusions 1584 are part of the third light emitting part 1530, the porous layer 1583 and/or protrusions 1584 may include a dopant. When the porous layer 1583 and/or the protrusions 1584 are the first conductivity-type semiconductor layer of the third light emitting part 1530, the dopant may include an n-type dopant.

The first light 301, the second light 302, and the third light 303 may be more easily extracted by protrusions 1584. In addition, the first light 301, the second light 302, and the third light 303 are scattered in various directions by the plurality of pores of the protrusions 1584, so that uniformly distributed light may be obtained.

Therefore, light extraction efficiency is improved by the protrusions 1584 and the plurality of pores of the protrusions 1584, uniformly distributed light is obtained, and luminance may be improved.

The protrusion 1584 as shown in FIG. 6, may be provided to easily separate the substrate 1110 from the semiconductor light emitting device 150 after the semiconductor light emitting device 150 is manufactured on the substrate 1110, the semiconductor light emitting device 150 is transferred onto the substrate 201. For example, the substrate 1110 may be separated using a mechanical lift-off (MLO) process. The MLO process may be a process of separating the substrate 1110 from the semiconductor device by applying physical or artificial force.

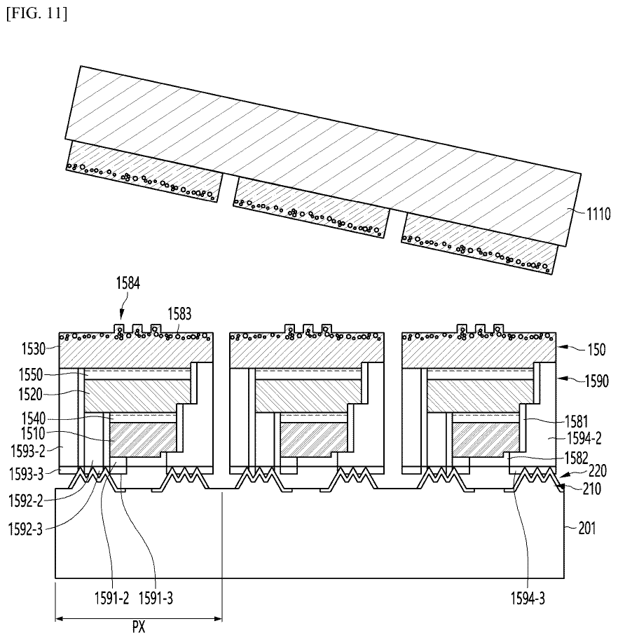

With reference to FIGS. 10 and 11, the manufacturing process of the display device 200 according to the first embodiment will be described.

FIGS. 10 and 11 show a process for manufacturing a display device by transferring the semiconductor light emitting device 150 of FIG. 6 onto the substrate 201.

As shown in FIG. 10, a substrate 1110 on which a plurality of semiconductor light emitting devices 150 are manufactured may be prepared.

In addition, a substrate 201 provided with an electrode pad part 220 may be provided for each of the plurality of pixels (PX). Although not shown, a driver for driving the semiconductor light emitting device 150 of each pixel (PX) may be built into the substrate 201. For example, the driving unit may be formed using a semiconductor process.

After turning over the substrate 1110, an alignment process may be performed so that the plurality of semiconductor light emitting devices 150 correspond to the plurality of electrode pad parts 220 on the substrate 201. At this time, the electrode 1590 of the semiconductor light emitting device 150 may face the electrode pad part 220. For example, as shown in FIGS. 12 and 13, the first electrode 1591 faces the first electrode pad 221, and the second electrode 1592 faces the second electrode pad 222. For example, the third electrode 1593 may face the third electrode pad 223, and the fourth electrode 1594 may face the fourth electrode pad 224. The first electrode pad 221, the second electrode pad 222, the third electrode pad 223, and the fourth electrode pad 224 may have a texture structure. The texture structure may have a spike shape 227.

As shown in FIG. 11, a relatively small pressure is applied to the substrate 1110 at room temperature, so that a plurality of semiconductor light emitting devices 150 on the substrate 1110 may be transferred to the substrate 201. As pressure is applied to the substrate 1110, the semiconductor light emitting device 150 may receive force in a downward direction. Accordingly, the electrode 1590 of the semiconductor light emitting device 150 and the electrode pad part 220 of the substrate 201 collide with each other, the spikes of the electrode pad part 220 may penetrate the surface of the electrode 1590 of the semiconductor light emitting device 150 and diffuse into the electrode 1590, thereby forming the diffusion layer 240. That is, the diffusion layer 240 may be formed on each of the first electrode 1591, the second electrode 1592, the third electrode 1593, and the fourth electrode 1594. Accordingly, the electrode 1590 and the electrode pad part 220 of the semiconductor light emitting device 150 are bonded by a room temperature bonding method, so that they may be electrically connected and strongly adhered.

Afterwards, by using the MLO process, a force is applied to pull the substrate 1110 in the upward direction, the semiconductor light emitting device 150 including the plurality of protrusions 1584 centered on the plurality of protrusions 1584 remains on the substrate 201, and the substrate 1110 may be separated.

Accordingly, a plurality of protrusions 1584 may be provided to easily separate the substrate 1110 when performing the MLO process.

In the past, selective transfer of a semiconductor light emitting device was performed using the LLO (Laser Lift-Off) process. In other words, the semiconductor light emitting device was separated by irradiating a laser between the semiconductor light emitting device to be transferred and the substrate. However, the LLO process uses expensive laser equipment, resulting in enormous facility investment costs and high process costs. However, in this embodiment, the substrate is separated by simply pulling the substrate by applying artificial force without using a laser, so facility investment costs and process costs may be reduced.

By separating the substrate 1110, the display device 200 including a plurality of semiconductor light emitting devices 150 may be manufactured.

Therefore, the first light 301, the second light 302, and the third light 303 are emitted simultaneously from each of the plurality of semiconductor light emitting devices 150, an image may be displayed by the first light 301, the second light 302, and the third light 303. At this time, light extraction efficiency may be improved by the plurality of protrusions 1584 or the porous layer 1583, thereby improving luminance.

FIGS. 14 to 18 explain a method of manufacturing the semiconductor light emitting device 150 of FIG. 6.

As shown in FIG. 14, at least one semiconductor layer 1112, a third light emitting part 1530, and a second selective penetration part 1550 may be formed on the substrate 1110.

The third light emitting part 1530 may include at least one first conductivity-type semiconductor layer formed on at least one semiconductor layer 1112, an active layer formed on a first conductivity-type semiconductor layer and at least one second conductivity-type semiconductor layer formed on the active layer. For example, the first conductivity-type semiconductor layer may include an n-type dopant, and the second conductivity-type semiconductor layer may include a p-type dopant.

At least one semiconductor layer 1112 may be included in at least one first conductivity-type semiconductor layer, but this is not limited.

At least one semiconductor layer 1112 may include a dopant. At this time, the concentration of the dopant included in each semiconductor layer 1112 may be different.

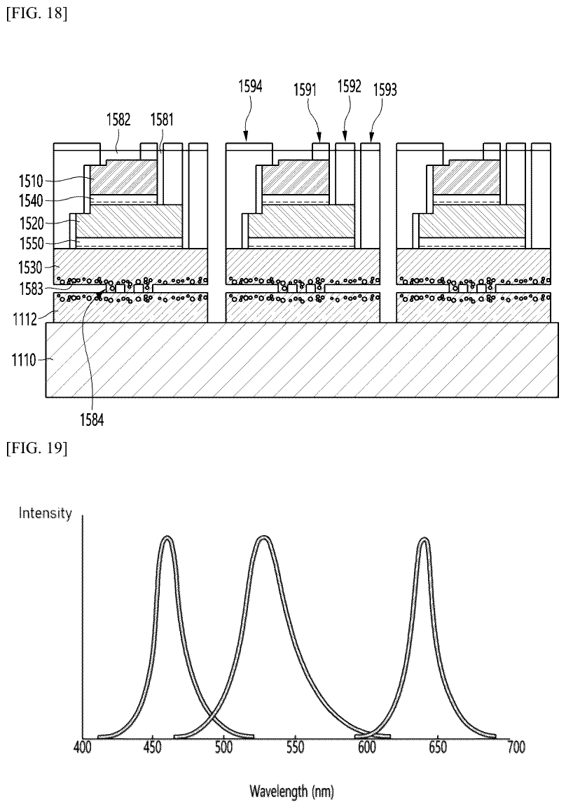

For example, at least one semiconductor layer 1112 includes a first semiconductor layer (1112-1 in FIG. 18), a second semiconductor layer 1112-2, and a third semiconductor layer sequentially formed on the substrate 1110. It may include 1112-3. At this time, the dopant concentration of the second semiconductor layer 1112-2 may be greater than the dopant concentration of the first semiconductor layer 1112-1 or the third semiconductor layer 1112-3. The first semiconductor layer 1112-1, the second semiconductor layer 1112-2, and the third semiconductor layer 1112-3 may include the same dopant, but are not limited thereto.

For example, using an electrochemical etching process, each of the first semiconductor layer 1112-1, the second semiconductor layer 1112-2, and the third semiconductor layer 1112-3 may be formed as a porous layer 1583 including a plurality of pores. In particular, the second semiconductor layer 1112-2, which has a high dopant concentration, uses an electrochemical etching process, may be formed as a porous layer 1583 connected in a plurality of patterns between the first semiconductor layer 1112-1 and the second semiconductor layer 1112-2. As will be explained later, after a plurality of semiconductor devices on the final manufactured substrate 1110 are transferred onto the display substrate 201, the substrate 1110 is forcibly separated using the MLO process, the plurality of patterns of the second semiconductor layer 1112-2 may be a plurality of protrusions 1584. If the substrate 1110 is separated, a plurality of patterns of the second semiconductor layer 1112-2 may remain as a plurality of protrusions 1584 on the first conductivity-type semiconductor layer of the third light emitting part 1530.

At least one semiconductor layer 1112, a first conductivity-type semiconductor layer 1112-1, an active layer 1112-2, and a second conductivity-type semiconductor layer 1112-3 may be grown on the substrate 1110 using deposition equipment such as MOCVD. Thereafter, a second selective penetration part 1550 having a DBR structure may be formed by stacking media layers having different refractive indices.

Meanwhile, although not shown, a third conductive layer (1580 in FIGS. 7 to 9) is formed between the third light emitting part 1530 and the second optional penetration part 1550, a second conductive layer 1570 may be formed on the second selective penetration part 1550. That is, after the third light emitting part 1530 is formed on the substrate 1110, a third conductive layer 1580, a second selective penetration part 1550, and a second conductive layer 1570 may be formed sequentially.

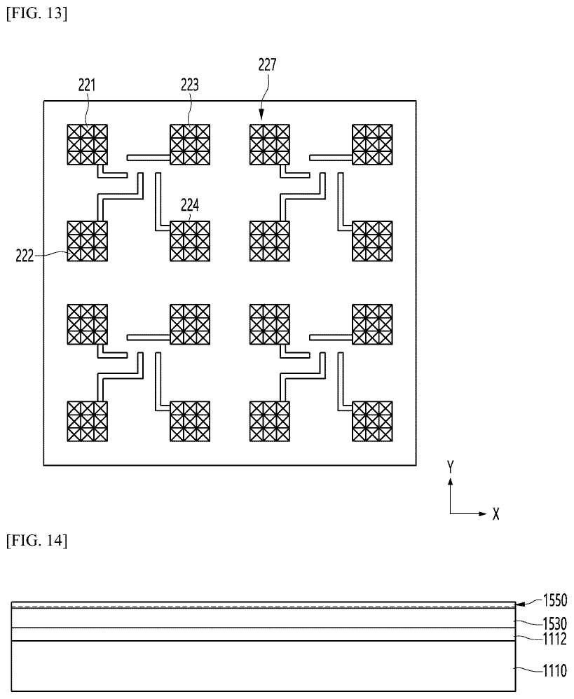

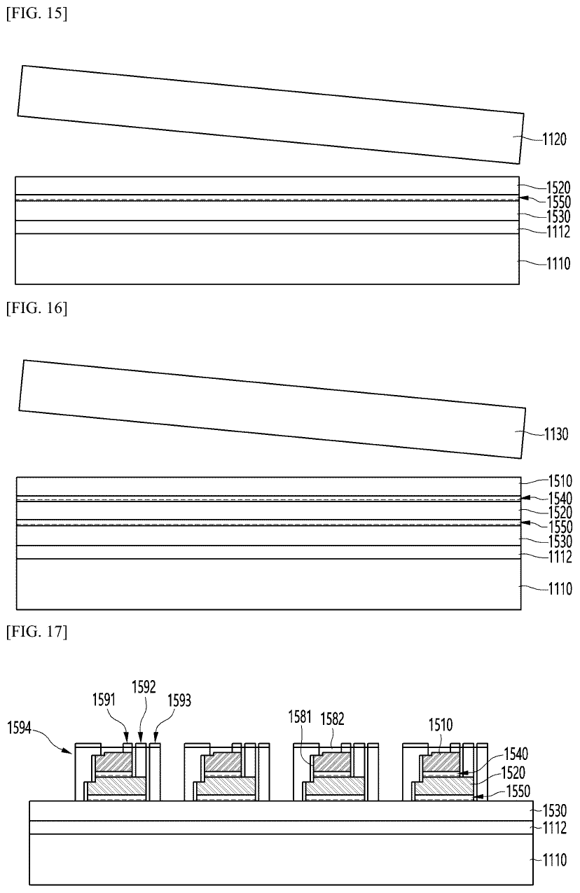

As shown in FIG. 15, a second light emitting part 1520 may be formed on the second selective penetration part 1550.

Specifically, a substrate 1120 equipped with a second light emitting part 1520 may be provided. Thereafter, after flipping the substrate 1120 over, the second light emitting part 120 may be attached to the second optional penetration part 1550. To this end, after the adhesive member is placed on the second optional penetration part 1550, the second light emitting part 1520 may be attached to the second optional penetration part 1550 through an adhesive member by performing a heat compression process. Afterwards, the substrate 1120 may be removed. For example, by using the LLO process to irradiate a laser between the substrate 1120 and the second light emitting part 1520, the substrate 1120 may be separated from the second light emitting part 1520.

Meanwhile, the second light emitting part 1520 may include at least one first conductivity-type semiconductor layer formed on the substrate 1120, an active layer formed on the first conductivity-type semiconductor layer and at least one second conductivity-type semiconductor layer formed on the active layer. For example, the first conductivity-type semiconductor layer may include an n-type dopant, and the second conductivity-type semiconductor layer may include a p-type dopant. The first conductivity-type semiconductor layer, the active layer, and the second conductivity-type semiconductor layer of the second light emitting part 1520 may be grown using deposition equipment such as MOCVD.

After the substrate 1120 is turned over, the second light emitting part 1520 is attached to the second selective penetration part 1550, as shown in FIG. 15, the second conductivity-type semiconductor layer of the second light emitting part 1520 is disposed on the second selective penetration part 1550, the active layer may be disposed on the second conductivity-type semiconductor layer, and the first conductivity-type semiconductor layer may be disposed on the active layer.

As shown in FIG. 16, after the first selective penetration part 1540 is formed on the second light emitting part 1520, the first light emitting part 1510 may be formed on the first selective penetration part 1540.

Specifically, a substrate 1130 provided with a first selective penetration part 1540 and a first light emitting part 1510 may be provided. Thereafter, after flipping the substrate 1130 over, the first optional penetration part 1540 may be attached to the second light emitting part 1520. To this end, after the adhesive member is placed on the second light emitting part 1520, a heat compression process may be performed to attach the first selective penetration part 1540 to the second light emitting part 1520 through the adhesive member. Afterwards, the substrate 1130 may be removed. For example, by using the LLO process to irradiate a laser between the substrate 1130 and the first light emitting part 1510, the substrate 1130 may be separated from the first light emitting part 1510.

Meanwhile, the first light emitting part 1510 includes at least one first conductivity-type semiconductor layer formed on the substrate 1130, an active layer formed on a first conductivity-type semiconductor layer and at least one second conductivity-type semiconductor layer formed on the active layer. The first conductivity-type semiconductor layer may include, for example, an n-type dopant, and the second conductivity-type semiconductor layer may include a p-type dopant. The first conductivity-type semiconductor layer, the active layer, and the second conductivity-type semiconductor layer of the first light emitting part 1510 may be grown using deposition equipment such as MOCVD.

After the substrate 1130 is turned over, the first selective penetration part 1540 is attached to the second light emitting part 1520, as shown in FIG. 16, the first optional penetration part 1540 is disposed on the second light emitting part 1520, the second conductivity-type semiconductor layer of the first light emitting part 1510 is disposed on the first optional penetration part 1540, the active layer may be disposed on the second conductivity-type semiconductor layer, and the first conductivity-type semiconductor layer is disposed on the active layer.

Meanwhile, although not shown, a first conductive layer (1560 in FIGS. 7 to 9) may be formed between the first light emitting part 1510 and the first selective penetration part 1540. For example, the first conductive layer 1560 may be formed directly on the second light emitting part 1520. For example, the first conductive layer 1560 may be formed on the substrate 1130 and then transferred onto the substrate 1110. That is, after the first light emitting part 1510 is formed on the substrate 1130, the first conductive layer 1560 is formed on the first light emitting part 1510, and a first selective penetration part 1540 may be formed on the first conductive layer 1560. Thereafter, after flipping the substrate 1130 over, as the first selective penetration part 1540 is attached to the second light emitting part 1520, the first conductive layer 1560 on the first selective penetration part 1540 may be transferred onto the substrate 1110.

As shown in FIG. 17, after etching the first light emitting part 1510, the first selective penetration part 1540, the second light emitting part 1520, and the second selective penetration part, a first insulating layer 1581 and a second insulating layer 1582 may be formed around each of the first light emitting part 1510, the first selective penetration part 1540, the second light emitting part 1520, and the second selective penetration part. Afterwards, residual electrodes 1590 may be formed on the first light emitting part 1510, the second light emitting part 1520, and the third light emitting part 1530.

As shown in FIG. 18, the third light emitting part 1530 is etched, thereby forming a plurality of semiconductor light emitting devices 150 on the substrate 1110.

One semiconductor device among the plurality of semiconductor devices shown in FIG. 18 is shown in FIG. 6.

After turning over the substrate 1110 shown in FIG. 18, a plurality of semiconductor light emitting devices 150 are bonded to the substrate 201 by applying pressure to the substrate 1110, by removing the substrate 1110 using the MLO process, the display device 200 may be manufactured (FIGS. 10 and 11).

### Second Embodiment

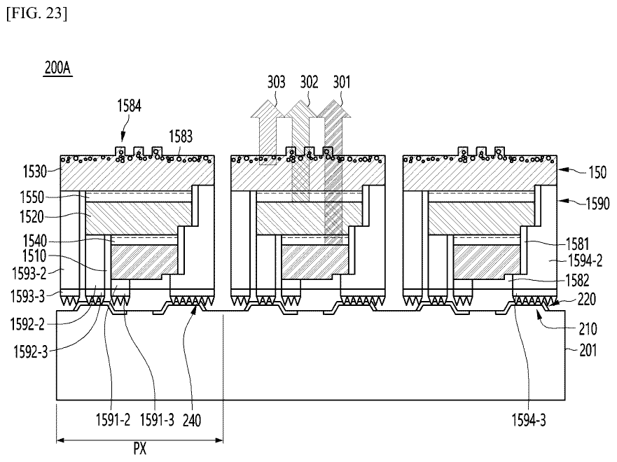

FIG. 23 is a cross-sectional view showing a display device according to a second embodiment.

The second embodiment is the same as the first embodiment except that the texture structure is formed in the electrode 1590. In the second embodiment, components having the same shape, structure, and/or function as those of the first embodiment are assigned the same reference numerals, and detailed descriptions are omitted.

Referring to FIG. 23, the display device 200A according to the second embodiment may include a substrate 201 and a semiconductor light emitting device 150.

The substrate 201 may include an electrode pad part 220. Although not shown, the electrode pad part 220 may include a first electrode pad 221, a second electrode pad 222, a third electrode pad 223, and a fourth electrode pad 224.

The semiconductor light emitting device 150 may include a first light emitting part 1510, a second light emitting part 1520, a third light emitting part 1530, a first optional penetration part 1540, a second optional penetration part 1550, a first insulating layer 1581, a second insulating layer 1582, and an electrode 1590.

For example, the electrode 1590 may include a first electrode 1591, a second electrode 1592, a third electrode 1593, and a fourth electrode 1594. For example, the first electrode 1591 is connected to the first light emitting part 1510, the second electrode 1592 is connected to the second light emitting part 1520, the third electrode 1593 is connected to the third light emitting part 1530, the fourth electrode 1594 may be commonly connected to the first light emitting part 1510, the second light emitting part 1520, and the third light emitting part 1530. For example, the first optional penetration part 1540 is disposed between the first light emitting part 1510 and the second light emitting part 1520, the second optional penetration part 1550 may be disposed between the second light emitting part 1520 and the third light emitting part 1530.

For example, the surfaces of the electrodes 1590, that is, the first electrode 1591, the second electrode 1592, the third electrode 1593, and the fourth electrode 1594, may have a texture structure. The texture structure may have a spike shape 227.

Pressure is applied to the semiconductor light emitting device 150, so that the electrode 1590 of the semiconductor light emitting device 150 and the electrode pad part 220 of the substrate 201 may be bonded. In this case, the spikes of each of the electrodes 1590, that is, the first electrode 1591, the second electrode 1592, the third electrode 1593, and the fourth electrode 1594 penetrates the surface of the first electrode pad 221, the second electrode pad 222, the third electrode pad 223, and the fourth electrode pad 224 of the substrate 201 and spreads therein, a diffusion layer 240 may be formed. That is, the diffusion layer 240 may be formed on each of the first electrode pad 221, the second electrode pad 222, the third electrode pad 223, and the fourth electrode pad 224.

The above detailed description should not be construed as restrictive in any respect and should be considered illustrative. The scope of the embodiment should be determined by reasonable interpretation of the appended claims, and all changes within the equivalent scope of the embodiment are included in the scope of the embodiment.

### INDUSTRIAL APPLICABILITY

The embodiment may be adopted in the field of displays that display images or information. The embodiment may be adopted in the display field for displaying images or information using a semiconductor light emitting device. The semiconductor light emitting device may be a micro-level semiconductor light emitting device or a nano-level semiconductor light emitting device.

For example, the embodiment may be adopted in TVs, signage, smart phones, mobile phones, mobile terminals, HUDs for automobiles, backlight units for laptops, and display devices for VR or AR.

1. A display device comprising:
a substrate comprising a plurality of pixels; and
a semiconductor light emitting device in each of the plurality of pixels,
wherein the substrate comprises an electrode pad part,
wherein the semiconductor light emitting device comprises an electrode,
wherein the electrode is disposed on the electrode pad part,
wherein at least one of the electrode pad part or the electrode comprises a texture structure, and
wherein the electrode and the electrode pad part are configured to overlap each other in a horizontal direction.

2. The display device according to claim 1, wherein the texture structure comprises a spike shape.

3. The display device according to claim 1, wherein at least one of the electrode pad part or the electrode comprises a diffusion layer.

4. The display device according to claim 3, wherein the electrode pad part and the electrode comprise gold.

5. The display device according to claim 1, wherein the substrate comprises a pattern portion, and
wherein the electrode pad part is disposed on the pattern portion.

6. The display device according to claim 5, wherein the pattern portion comprises a first pattern comprising a first texture, a second pattern comprising a second texture, a third pattern comprising a third texture and a fourth pattern comprising a fourth texture,
wherein the first to fourth patterns are disposed on a same layer.

7. The display device according to claim 6, wherein the electrode pad part comprises a first electrode pad on the first pattern, a second electrode pad on the second pattern, a third electrode pad on the third pattern and a fourth electrode pad on the fourth pattern, and
wherein the first to fourth electrode pads are disposed on a same layer.

8. The display device according to claim 7, wherein a surface of each of the first to fourth electrode pads comprises a shape corresponding to a shape of the surface of each of the first to fourth patterns.

9. The display device according to claim 7, wherein the semiconductor light emitting device is disposed on the first to fourth electrode pads.

10. The display device according to claim 7, wherein the semiconductor light emitting device comprises a first light emitting part to generate first light, a second light emitting part to generate second light and a third light emitting part to generate third light, and
wherein the first light emitting part, the second light emitting part, and the third light emitting part comprise a vertically stacked structure.

11. The display device according to claim 10, wherein the first light comprises red light, the second light comprises green light, and the third light comprises blue light.

12. The display device according to claim 10, wherein the second light emitting part is disposed on the first light emitting part, and the third light emitting part is disposed on the second light emitting part.

13. The display device according to claim 10, wherein a second diameter of the second light emitting part is larger than a first diameter of the light emitting part, and a third diameter of the third light emitting part is larger than the second diameter of the second light emitting part.

14. The display device according to claim 10, wherein the electrode comprises a first electrode on a first side of the first light emitting part, a second electrode on a first side of the second light emitting part, a third electrode on a first side of the third light, and a fourth electrode on a second side of each of the first light emitting part, the second light emitting part, and the third light emitting part.

15. The display device according to claim 14, wherein the first electrode is disposed on the first electrode pad, the second electrode is disposed on the second electrode pad, the third electrode is disposed on the third electrode pad and the fourth electrode is disposed on the fourth electrode pad.

16. The display device according to claim 14, wherein each of the first electrode, the second electrode, the third electrode, and the fourth electrode comprises different length.

17. The display device according to claim 10, wherein the semiconductor light emitting device comprises a first selective penetration part between the first light emitting part and the second light emitting part, and a second selective penetration part between the second light emitting part and the third light emitting part.

18. The display device according to claim 17, wherein the semiconductor light emitting device comprises a first conductive layer disposed between the first light emitting part and the first selective penetration part and electrically connected to the first electrode, a second conductive layer disposed between the first selective penetration part and the second light emitting part and electrically connected to the second electrode, and a second conductive layer disposed between the first selective penetration part and the second light emitting part and electrically connected to the second electrode.

19. The display device according to claim 10, wherein the semiconductor light emitting device comprises a porous layer on the third light emitting part and a protrusion on the third light emitting part.

20. The display device according to claim 19, wherein the porous layer and the protrusion comprise a dopant.
